(19) United States
(12) Patent Application Publication
(10) Pub. No.: US 2025/0031341 A1
(43) Pub. Date: Jan. 23, 2025

(54) COOLING MODULE, ELECTRONIC SYSTEM AND CONTROL METHOD THEREOF

(71) Applicant: Wiwynn Corporation, New Taipei City (TW)

(72) Inventors: Yi Cheng, New Taipei City (TW); Tai-Ying Tu, New Taipei City (TW); Tsung-Han Li, New Taipei City (TW)

(21) Appl. No.: 18/403,850

(22) Filed: Jan. 4, 2024

(30) Foreign Application Priority Data
Jul. 21, 2023 (TW) 112127401

(51) Int. Cl. H05K 7/20

(52) U.S. Cl. CPC H05K 7/20254; H05K 7/20263; H05K 7/20272

(57) ABSTRACT

An electronic system includes a heat source and a cooling module. The cooling module includes a cold plate and a thermally conductive component. The cold plate has a fluid chamber, a thermally coupling surface and a heat dissipation surface, the fluid chamber is located between the thermally coupling surface and the heat dissipation surface, and the thermally coupling surface is thermally coupled with the heat source. The thermally conductive component is thermally coupled with the cold plate. The thermally conductive component extends from one side of the cold plate located closer to the thermally coupling surface to another side of the cold plate located closer to the heat dissipation surface.

### CROSS-REFERENCE TO RELATED APPLICATIONS

This non-provisional application claims priority under 35 U.S.C. § 119 (a) on Patent Application No(s). 112127401 filed in Taiwan, R.O.C. on Jul. 21, 2023, the entire contents of which are hereby incorporated by reference.

### TECHNICAL FIELD

The disclosure relates to a cooling module, an electronic system and a control method thereof.

### BACKGROUND

In the present, a server employs a liquid cooling system for dissipating heat generated by a heat source, such as a CPU. In the liquid cooling system, a cold plate is thermally coupled to the heat source so as to allow the heat generated by the heat source to be conducted to the cold plate. As a result, coolant flowing through the cold plate can carry away the heat for enabling the heat source to operate at an appropriate temperature.

In general, a valve is typically disposed on a pipeline connected to the cold plate. The valve can be closed when a leakage occurs in the pipeline or the cold plate for preventing the coolant from keeping flowing therethrough. However, after the valve is closed, the heat dissipation efficiency of the cold plate is significantly reduced and is insufficient to the cooling requirements of the heat source due to lacking of coolant in the cold plate. Therefore, in such a case, the temperature of the heat source may rapidly increase, such that the heat source may be easily damaged.

### SUMMARY

One embodiment of the disclosure provides an electronic system. The electronic system includes a heat source and a cooling module. The cooling module includes a cold plate and a thermally conductive component. The cold plate has a fluid chamber, a thermally coupling surface and a heat dissipation surface, the fluid chamber is located between the thermally coupling surface and the heat dissipation surface, and the thermally coupling surface is thermally coupled with the heat source. The thermally conductive component is thermally coupled with the cold plate. The thermally conductive component extends from one side of the cold plate located closer to the thermally coupling surface to another side of the cold plate located closer to the heat dissipation surface.

Another embodiment of the disclosure provides a cooling module. The cooling module is configured to cool a heat source. The cooling module includes a liquid cooling assembly. The liquid cooling assembly includes a cold plate and a thermally conductive component. The cold plate has a fluid chamber, a thermally coupling surface and a heat dissipation surface, the fluid chamber is located between the thermally coupling surface and the heat dissipation surface, and the thermally coupling surface is configured to be thermally coupled with the heat source. The thermally conductive component is thermally coupled with the cold plate. The thermally conductive component extends from one side of the cold plate located closer to the thermally coupling surface to another side of the cold plate located closer to the heat dissipation surface.

Still another embodiment of the disclosure provides a control method of electronic system. The control method includes monitoring a leakage detector via a module controller, and when the module controller receives a leakage signal transmitted from the leakage detector, the module controller closes a valve connected to a cold plate and activates an air cooling assembly for generating an airflow towards a fin assembly thermally coupled with the cold plate.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a schematic view of an electronic system according to a first embodiment of the disclosure;

FIG. 2 is a perspective view of a liquid cooling assembly, an air cooling assembly, a heat source and a support seat in FIG. 1;

FIG. 3 is an exploded view of the liquid cooling assembly, the air cooling assembly, the heat source and the support seat in FIG. 2;

FIG. 4 is a bottom perspective view of the liquid cooling assembly in FIG. 3;

FIG. 5 is a cross-sectional view of the liquid cooling assembly, the heat source and the support seat in FIG. 2;

FIG. 6 is a block diagram of the electronic system in FIG. 1;

FIG. 7 is a flow chart of a control method in conjunction with the electronic system in FIG. 1;

FIG. 8 is a schematic view of the electronic system in FIG. 1 when the liquid cooling assembly experiences a leakage; and

FIG. 9 is a cross-sectional view of a liquid cooling assembly, a heat source and a support seat according to a second embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

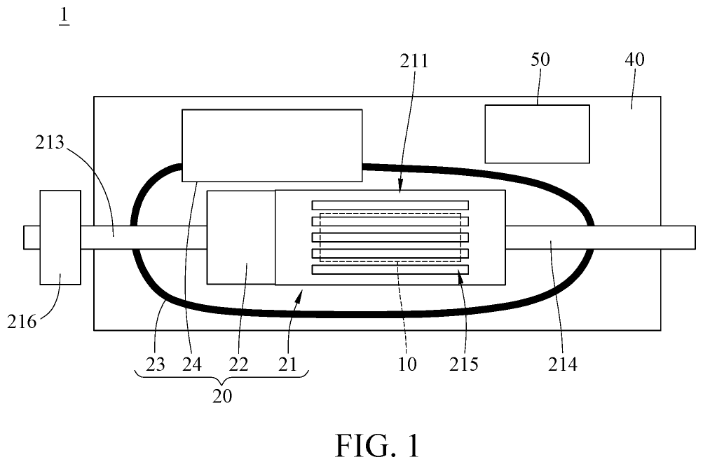

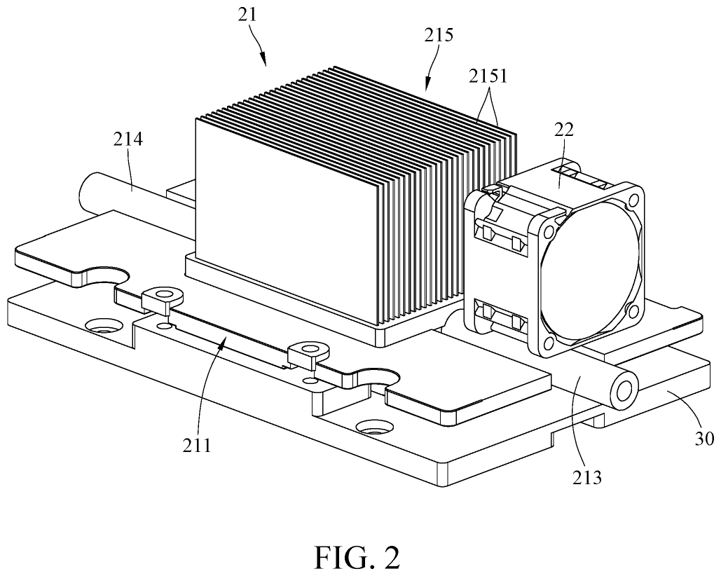

Referring to FIGS. 1 and 2, FIG. 1 is a schematic view of an electronic system 1 according to a first embodiment of the disclosure, and FIG. 2 is a perspective view of a liquid cooling assembly 21, an air cooling assembly 22, a heat source 10 and a support seat 30 in FIG. 1.

In this embodiment, the electronic system 1 is, for example, a server system. The electronic system 1 includes a heat source 10 and a cooling module 20. In addition, the electronic system 1 may further include a support seat 30, a motherboard 40 and a baseboard management controller 50.

The heat source 10 is, for example, a chip that may generate heat, such as a CPU or a GPU. The heat source 10 is disposed on the motherboard 40 via the support seat 30. The baseboard management controller 50 is disposed on the motherboard 40 and is electrically connected to the heat source 10 via the motherboard 40. The electrical connection between the baseboard management controller 50 and the heat source 10 represents that a signal can be transmitted between the baseboard management controller 50 and the heat source 10. Similarly, the electrical connection between two components described later also represents that a signal can be transmitted therebetween.

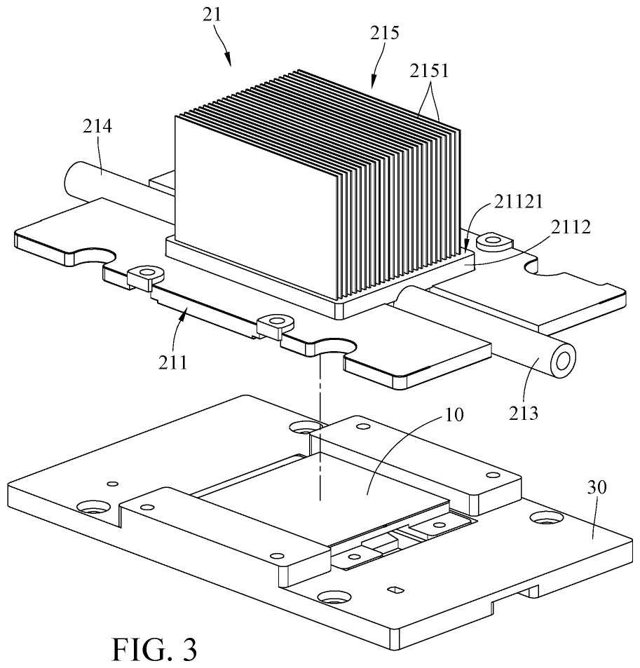

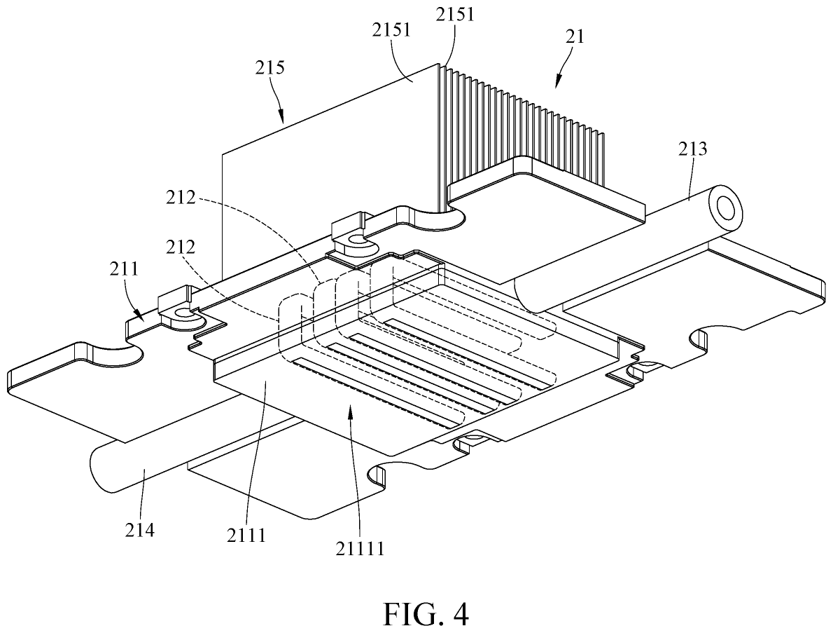

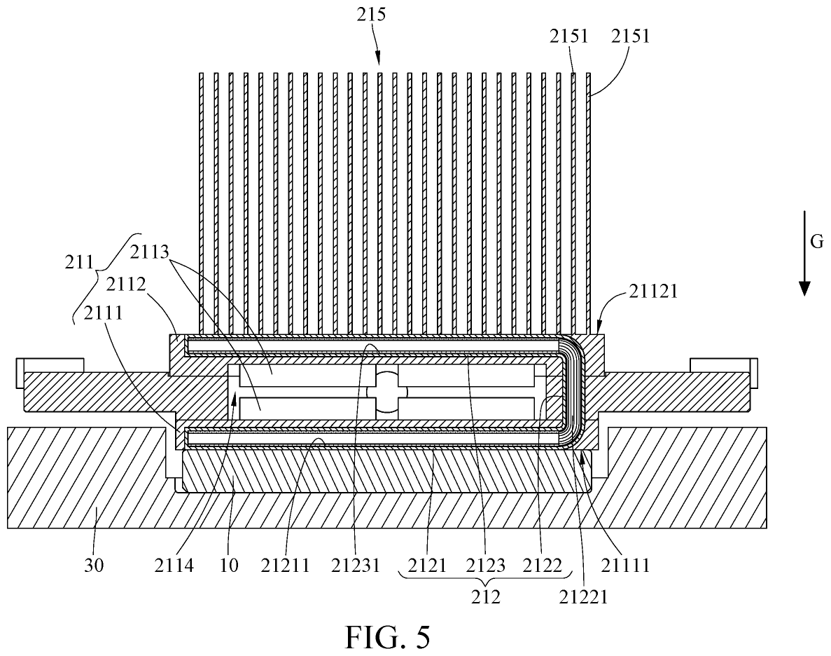

Referring to FIGS. 3 to 5, FIG. 3 is an exploded view of the liquid cooling assembly 21, the air cooling assembly 22, the heat source 10 and the support seat 30 in FIG. 2, FIG. 4 is a bottom perspective view of the liquid cooling assembly 21 in FIG. 3, and FIG. 5 is a cross-sectional view of the liquid cooling assembly 21, the heat source 10 and the support seat 30 in FIG. 2.

The cooling module 20 includes a liquid cooling assembly 21. The liquid cooling assembly 21 includes a cold plate 211 and a plurality of thermally conductive components 212. The cold plate 211 includes a bottom seat 2111 and a cover 2112 connected to each other. In addition, the cold plate 211 may further include a plurality of fins 2113. The bottom seat 2111 has a thermally coupling surface 21111, and the cover 2112 has a heat dissipation surface 21121. The bottom seat 2111 and the cover 2112 together form a fluid chamber 2114, and the fluid chamber 2114 is located between the thermally coupling surface 21111 and the heat dissipation surface 21121. The fluid chamber 2114 is configured for a coolant (not shown) to flow therethrough. The fins 2113 are located in the fluid chamber 2114, some of the fins 2113 are connected to the bottom seat 2111, and the others of the fins 2113 are connected to the cover 2112. The thermally coupling surface 21111 of the bottom seat 2111 is thermally coupled to the heat source 10, such that heat generated by the heat source 10 can be conducted to the bottom seat 2111, the cover 2112 and the fins 2113. As a result, when the coolant flows through the fluid chamber 2114, the coolant can take away heat absorbed by the bottom seat 2111, the cover 2112 and the fins 2113.

In this embodiment, the liquid cooling assembly 21 may further include an inlet pipe 213 and an outlet pipe 214. The inlet pipe 213 and the outlet pipe 214 are respectively connected to different positions of the cold plate 211 and are in fluid communication with the fluid chamber 2114. The inlet pipe 213, the outlet pipe 214, the cold plate 211, a pump (not shown) and a heat radiator (not shown) may form a liquid cooling loop. The pump can drive to the coolant to flow in the liquid cooling loop, such that the coolant can flow into the fluid chamber 2114 of the cold plate 211 through the inlet pipe 213 so as to perform a heat exchange with the bottom seat 2111, the cover 2112 and the fins 2113. After the coolant flows out of the fluid chamber 2114 of the cold plate 211, the coolant can flow to the heat radiator through the outlet pipe 214 for being cooled. As a result, the cooled coolant can return to the fluid chamber 2114 of the cold plate 211 to perform the heat exchange with the bottom seat 2111, the cover 2112 and the fins 2113.

The thermally conductive components 212 are, for example, heat pipes. Thermal conductivities of the thermally conductive components 212 are, for example, greater than a thermal conductivity of the cold plate 211, but the disclosure is not limited thereto. The thermally conductive components 212 are embedded into the bottom seat 2111 and the cover 2112 of the cold plate 211. The thermally conductive components 212 are the same in structure, and thus the following merely introduces one of them in detail. The thermally conductive component 212 is, for example but not limited to, a U-shaped heat pipe. The thermally conductive component 212 includes a heat absorbing portion 2121, a transmission portion 2122 and a condensation portion 2123. The heat absorbing portion 2121 is connected to the condensation portion 2123 via the transmission portion 2122. The heat absorbing portion 2121 is disposed in the bottom seat 2111, and the heat absorbing portion 2121 is, for example, exposed from the thermally coupling surface 21111 of the bottom seat 2111 so as to be thermally coupled to the heat source 10. The condensation portion 2123 is disposed in the cover 2112 and is exposed from the heat dissipation surface 21121 of the cover 2112. The transmission portion 2122 extends from the bottom seat 2111 to the cover 2112; that is, the thermally conductive component 212 extends from one side of the cold plate 211 located closer to the thermally coupling surface 21111 to another side of the cold plate 211 located closer to the heat dissipation surface 21121, which facilitates to rapidly conduct heat generated by the heat source 10 to one side of the cold plate 211 located farther away from the heat source 10 so as to uniformly distribute heat all over the entire cold plate 211.

In this embodiment, the heat absorbing portion 2121 and the condensation portion 2123 is, for example, non-parallel to a direction G of gravity. In other words, the heat absorbing portion 2121 and the condensation portion 2123 may have a tendency to extend horizontally or transversely. Specifically, the heat absorbing portion 2121 and the condensation portion 2123 of this embodiment extend horizontally and is perpendicular to the direction G of gravity. Capillary structures 21211 and 21231 are respectively provided in the heat absorbing portion 2121 and the condensation portion 2123, and a groove structure 21221 is provided in the transmission portion 2122. After working fluid (not shown) in the thermally conductive component 212 absorbs heat generated by the heat source 10 in the heat absorbing portion 2121 and is vaporized, the vaporized working fluid flows to the condensation portion 2123 through the transmission portion 2122, and thus the vaporized working fluid is condensed into the liquid working fluid. The capillary structure 21231 in the condensation portion 2123, the groove structure 21221 in the transmission portion 2122 and the capillary structure 21211 in the heat absorbing portion 2121 facilitate the condensed liquid working fluid to flow back to the heat absorbing portion 2121, such that the working fluid can absorb heat generated by the heat source 10 in the heat absorbing portion 2121.

Note that the quantity of the thermally conductive components 212 are not restricted in the disclosure and may be modified to be one in some other embodiments. In addition, the thermally conductive component 212 is not restricted to be entirely a heat pipe; in some other embodiments, the heat absorbing portion and the condensation portion of the thermally conductive component may be vapor chambers, and the transmission portion is a heat pipe. Moreover, the heat absorbing portion 2121 and the condensation portion 2123 of the thermally conductive component 212 are not restricted to be exposed from the thermally coupling surface 21111 and the heat dissipation surface 21121, respectively; in some other embodiments, the heat absorbing portion and the condensation portion of the thermally conductive component may be entirely embedded into the bottom seat and the cover of the cold plate so as not to be exposed from the thermally coupling surface and the heat dissipation surface, respectively. In another embodiment, the thermally conductive component may not be embedded into the cold plate, but located around an outer periphery of the cold plate.

In this embodiment, the liquid cooling assembly 21 may further include a fin assembly 215. Fins 2151 of the fin assembly 215 are parallel to the direction G of gravity, and the fins 2151 are directly connected to and thermally coupled to the heat dissipation surface 21121 of the cover 2112 of the cold plate 211 and the condensation portion 2123 of the thermally conductive component 212. Therefore, the cover 2112 of the cold plate 211 and the thermally conductive component 212 can conduct heat generated by the heat source 10 to the fins 2151 of the fin assembly 215.

Note that the fins 2151 of the fin assembly 215 are not restricted to being parallel to the direction G of gravity, and the fins 2151 are not restricted to being directly connected to the heat dissipation surface 21121 of the cover 2112 of the cold plate 211. In some other embodiments, the fins of the fin assembly may be perpendicular to the direction of gravity and may not be directly connected to the heat dissipation surface of the cover of the cold plate. In such a case, the thermally conductive component may be in an L shape, and the thermally conductive component may pass through the lateral portion of the cold plate from the bottom of the cold plate, extend upwards along a direction from one side of the cold plate located closer to the thermally coupling surface to another side of the cold plate located closer to the heat dissipation surface, and penetrate through the fins of the fin assembly. Alternatively, the thermally conductive component may be in a U shape, and the thermally conductive component may pass through two opposite sides of the cold plate from the bottom of the cold plate, extend upwards along a direction from one side of the cold plate located closer to the thermally coupling surface to another side of the cold plate located closer to the heat dissipation surface, and penetrate through the fins of the fin assembly.

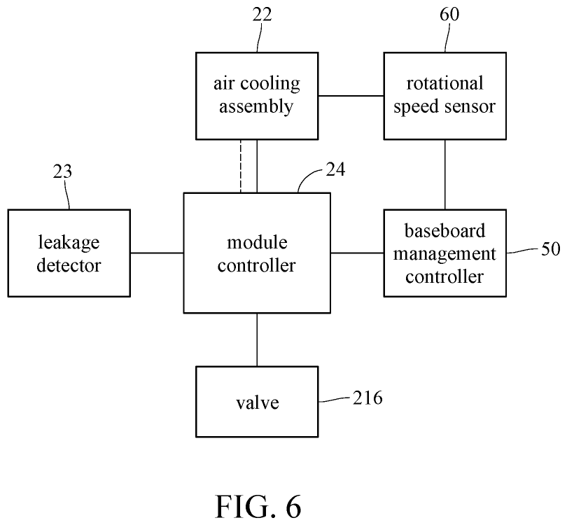

Then, referring to FIGS. 1 and 6, FIG. 6 is a block diagram of the electronic system 1 in FIG. 1.

In this embodiment, the cooling module 20 may further include an air cooling assembly 22. The air cooling assembly 22 is, for example, a fan assembly. The air cooling assembly 22 is disposed aside the fin assembly 215 for generating an airflow towards the fin assembly 215.

In this embodiment, the liquid cooling assembly 21 may further include a valve 216, and the cooling module 20 may further include a leakage detector 23 and a module controller 24. The valve 216 is disposed on the inlet pipe 213 for controlling whether the coolant flows into the cold plate 211 through the inlet pipe 213 or not. The leakage detector 23 is, for example, a leakage detection rope. The leakage detector 23 is disposed around the liquid cooling assembly 21. For example, the leakage detector 23 surrounds the cold plate 211 and passes by the inlet pipe 213 and the outlet pipe 214. The module controller 24 is electrically connected to the valve 216, the leakage detector 23, the air cooling assembly 22 and the baseboard management controller 50. The module controller 24 may be a module installed on the motherboard 40 (e.g., a control circuit board independent from the motherboard 40) or a circuit or a chip integrated on the motherboard 40. The module controller 24 may transmit not only a signal to the air cooling assembly 22 (e.g., as indicated by a solid line in FIG. 6), but also electricity to the air cooling assembly 22 (e.g., as indicated by a dash line in FIG. 6). In this embodiment, the electronic system 1 may further include a rotational speed sensor 60. The rotational speed sensor 60 is, for example, electrically connected to the air cooling assembly 22 and the baseboard management controller 50. The rotational speed sensor 60 is configured to measure a rotational speed of the air cooling assembly 22.

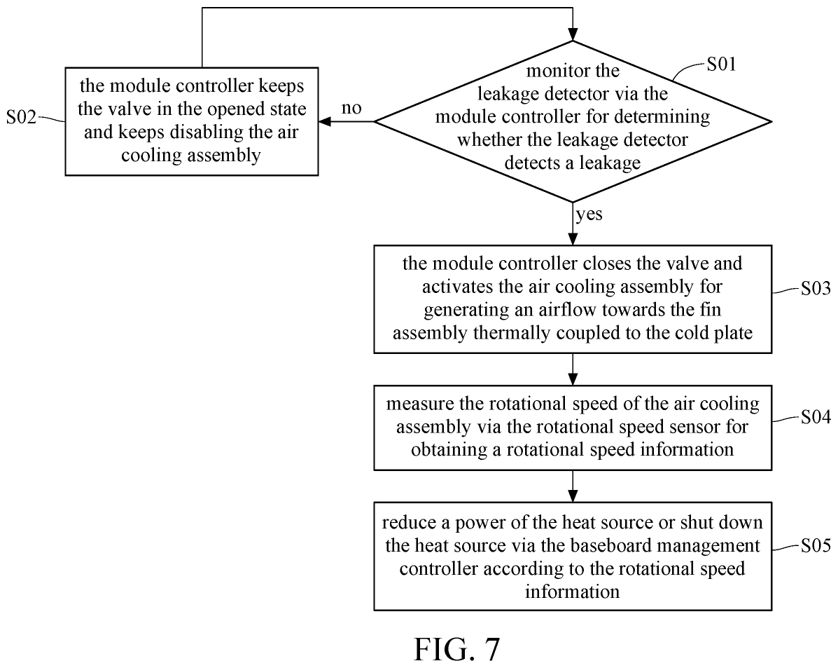

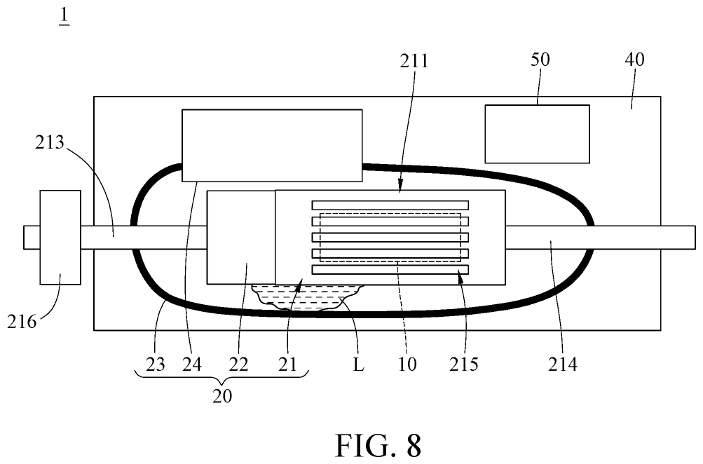

Then, the following paragraphs will introduce a control method in conjunction with the electronic system 1. Referring to FIGS. 6 to 8, FIG. 7 is a flow chart of a control method in conjunction with the electronic system 1 in FIG. 1, and FIG. 8 is a schematic view of the electronic system 1 in FIG. 1 when the liquid cooling assembly 21 experiences a leakage.

The following explanation is provided with a condition that the electronic system 1 is in operation, and the module controller 24 drives the valve 216 to be in an opened state and disables the air cooling assembly 22; that is, the cooling module 20 mainly dissipates heat generated by the heat source 10 in a liquid cooling mode.

In the control method, a step S01 is performed firstly to monitor the leakage detector 23 via the module controller 24 for determining whether the leakage detector 23 detects a leakage. When the leakage detector 23 does not detect a leakage, a step S02 is performed so that the module controller 24 keeps the valve 216 in the opened state and keeps disabling the air cooling assembly 22. Taking the leakage detector 23 as the leakage detection rope for instance, in the condition that the liquid cooling assembly 21 does not experience a leakage, the leakage detector 23 is not wet by the coolant, and thus the circuit of the leakage detector 23 is not conducted. At this moment, the leakage detector 23 does not produce a leakage signal, and thus the module controller 24 will not receive the leakage signal transmitted from the leakage detector 23 so as to keep the valve 216 in the opened state and keep disabling the air cooling assembly 22.

In this embodiment, the thermally conductive components 212 are thermally coupled to the cold plate 211, and the thermally conductive components 212 extend from one side of the cold plate 211 located closer to the thermally coupling surface 21111 to another side of the cold plate 211 located closer to the heat dissipation surface 21121, such that heat generated by the heat source 10 can be rapidly conducted to one side of the cold plate 211 located farther away from the heat source 10 so as to uniformly distribute heat throughout the entire cold plate 211. From computer simulation results of the cold plate with or without the thermally conductive components in the liquid cooling mode, compared with the cold plate without the thermally conductive components, the thermal resistance of the cold plate 211 with the thermally conductive components 212 in this embodiment can be reduced from 0.06 C/W to 0.032 C/W. As a result, the heat exchange efficiency between the cold plate 211 and the coolant flowing through the cold plate 211 can be improved, such that the coolant can carry away a larger amount of heat.

In the step S01, when the leakage detector 23 detects a leakage, a step S03 is performed so that the module controller 24 closes the valve 216 and activates the air cooling assembly 22 for generating an airflow towards the fin assembly 215 thermally coupled to the cold plate 211. For example, as shown in FIG. 8, when the liquid cooling assembly 21 experiences a leakage (e.g., when the coolant L leaks from a broken portion of the inlet pipe 213, the outlet pipe 214 or the cold plate 211, or from the place where the inlet pipe 213 or the outlet pipe 214 is connected to the cold plate 211), the leaking coolant may, for example, wet the leakage detector 23 so as to conduct the circuit of the leakage detector 23, such that the leakage detector 23 produces a leakage signal (e.g., a signal of 3 volts). After the leakage detector 23 transmits the leakage signal to the module controller 24, the module controller 24 closes the valve 216 and activates the air cooling assembly 22, for example, through an activation signal of 3 volts, such that the cooling module 20 is changed to dissipate heat generated by the heat source 10 in an air cooling mode at this moment.

In this embodiment, the thermally conductive components 212 can conduct heat generated by the heat source 10 to one side of the cold plate 211 located farther away from the heat source 10 for uniformly distributing heat all over the entire cold plate 211. As a result, in the case of a leakage causing the valve 216 connected to the cold plate 211 to closed, even though the cold plate 211 lacks of the coolant entering thereto, the cold plate 211 may still provide a certain level of heat dissipation effect to the heat source 10.

In addition, the thermally conductive components 212 are thermally coupled to the cold plate 211, and the thermally conductive components 212 extend from one side of the cold plate 211 located closer to the thermally coupling surface 21111 to another side of the cold plate 211 located closer to the heat dissipation surface 21121, which can rapidly conduct heat to the fin assembly 215 thermally coupled to the heat dissipation surface 21121 when the valve 216 connected to the cold plate 211 is closed due to a leakage. For example, from computer simulation results in the air cooling mode, compared to a cold plate with the fin assembly but without the thermally conductive components, the thermal resistance of the cold plate 211 with the thermally conductive components 212 and the fin assembly 215 in this embodiment can be reduced from 0.28 C/W to 0.13 C/W. As a result, the large heat dissipation surface of the fin assembly 215 can be effectively used for helping to dissipate heat generated by the heat source 10.

Furthermore, when the module controller 24 receives the leakage signal transmitted from the leakage detector 23, the module controller 24 closes the valve 216 connected to the cold plate 211 and activates the air cooling assembly 22 for generating airflow towards the fin assembly 215 thermally coupled to the cold plate 211, which can carry away the heat conducted to the cold plate 211 and the fin assembly 215 in a forced convection manner for further facilitating heat dissipation for the heat source 10.

On the other hand, since the valve 216 and the air cooling assembly 22 both are controlled by the module controller 24, the closing of the valve 216 and the activation of the air cooling assembly 22 can be performed by the module controller 24 simultaneously. Therefore, in a condition that the heat source 10 is unable to be cooled by the liquid cooling manner due to a leakage, the air cooling manner can be immediately adopted to dissipate heat generated by the heat source 10, thereby provide a certain level of heat dissipation effect to the heat source 10. As a result, even though the operation of the heat source 10 is required to wait for a period of time to be adjusted (e.g., reduced power or shut down) by the baseboard management controller 50 which controls various electronic components at the same time, the air cooling manner is adopted during this period of time to dissipate heat generated by the heat source 10, which prevents the heat source 10 from being damaged due to overly high temperature.

Note that the air cooling assembly 22 is an optional component; in some other embodiments, the cooling module may not include the air cooling assembly. In the case that the valve connected to the cold plate is closed due to a leakage, the cooling module may remove heat through natural convection. In addition, the fin assembly 215 is also an optional component and may be omitted in some other embodiments.

Then, continue to illustrate the control method. After the step S03, a step S04 is performed to measure the rotational speed of the air cooling assembly 22 via the rotational speed sensor 60 for obtaining a rotational speed information. Then, a step S05 is performed to reduce a power of the heat source 10 or shut down the heat source 10 via the baseboard management controller 50 according to the rotational speed information. For example, after the air cooling assembly 22 starts to operate, the rotational speed sensor 60 may transmit the measured rotational speed information of the air cooling assembly 22 to the baseboard management controller 50. Then, the baseboard management controller 50 compares the rotational speed information with a predetermined value. When the rotational speed information is greater than or equal to the predetermined value, it represents that the air cooling assembly 22 is operating normally, and the heat source 10 can still be cooled through forced convection, and thus the baseboard management controller 50 merely reduces the power of the heat source 10. Conversely, when the rotational speed information is smaller than the predetermined value, it represents that the air cooling assembly 22 is operating abnormally or in malfunction. At this moment, the heat source 10 is not cooled by the liquid cooling manner and the air cooling manner, and thus the baseboard management controller 50 shuts down the heat source 10 for preventing the heat source 10 from being damaged due to overly high temperature.

Note that the aforementioned steps S04 and S05 are optional and may be omitted in some other embodiments.

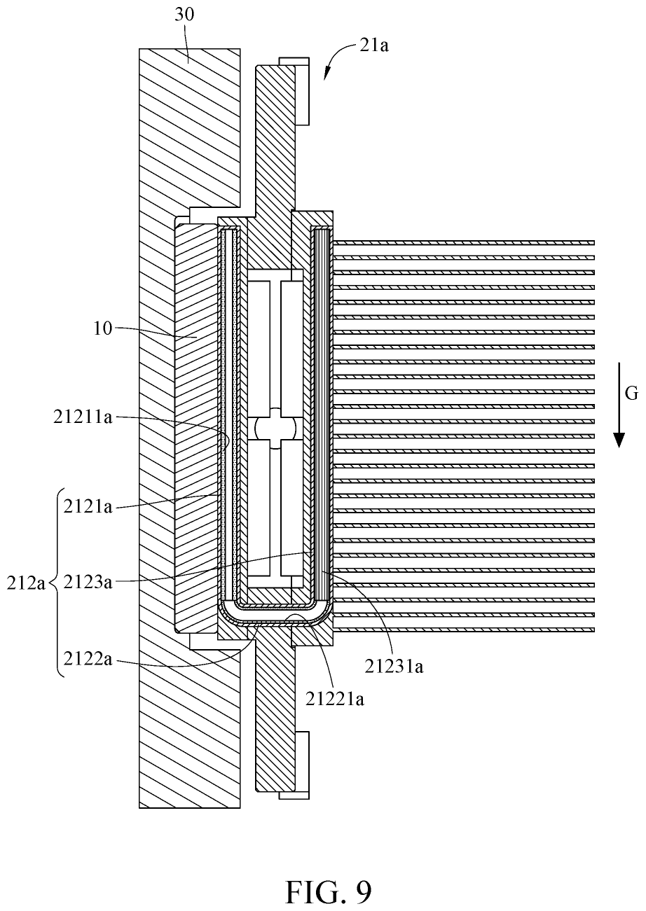

Then, referring to FIG. 9, FIG. 9 is a cross-sectional view of a liquid cooling assembly 21a, a heat source 10 and a support seat 30 according to a second embodiment of the disclosure.

The liquid cooling assembly 21a, the heat source 10 and the support seat 30 of this embodiment is similar to the liquid cooling assembly 21, the heat source 10 and the support seat 30 of the previous embodiment, the main differences between them are the placement direction of the liquid cooling assembly, the heat source and the support seat and the structure inside thermally conductive component, and thus the following paragraph merely introduces the main difference between them, and the same parts between them will not be repeatedly introduced hereinafter.

In this embodiment, the liquid cooling assembly 21a, the heat source 10 and the support seat 30 are placed vertically, and a heat absorbing portion 2121a and a condensation portion 2123a of a thermally conductive component 212a of the liquid cooling assembly 21a are, for example, non-perpendicular to the direction G of gravity; that is, the heat absorbing portion 2121a and the condensation portion 2123a have a tendency to extend vertically or upwards. Specifically, the heat absorbing portion 2121a and the condensation portion 2123a of the thermally conductive component 212a of this embodiment extends from a transmission portion 2122a along a direction, and this direction is parallel and opposite to the direction G of gravity. Capillary structures 21211a and 21221a are provided in the heat absorbing portion 2121a and the transmission portion 2122a of the thermally conductive component 212a, respectively, and a capillary force of the capillary structure 21211a in the heat absorbing portion 2121a of the thermally conductive component 212a is greater than a capillary force of the capillary structure 21221a in the transmission portion 2122a. A groove structure 21231a is provided in the condensation portion 2123a of the thermally conductive component 212a. The groove structure 21231a in the condensation portion 2123a of the thermally conductive component 212a can help the condensed liquid working fluid (not shown) to flow to the transmission portion 2122a along the direction G of gravity. The capillary structure 21221a in the transmission portion 2122a of the thermally conductive component 212a can help the condensed liquid working fluid to flow to the heat absorbing portion 2121a along a horizontal direction (e.g., perpendicular to the direction G of gravity). The large capillary force provided by the capillary structure 21211a in the heat absorbing portion 2121a of the thermally conductive component 212a can help the condensed liquid working fluid to resist gravity to flow upwards.

According to the cooling module, the electronic system, and the control method thereof as discussed in the above embodiments, the thermally conductive components are thermally coupled to the cold plate, and the thermally conductive components extend from one side of the cold plate located closer to the thermally coupling surface to another side of the cold plate located closer to the heat dissipation surface, such that heat generated by the heat source can be rapidly conducted to one side of the cold plate located farther away from the heat source so as to uniformly distribute heat all over the entire cold plate. As a result, in the case that a leakage occurs and thus the valve connected to the cold plate is closed, even though the cold plate lacks of the coolant entering thereto, the combination of the cold plate and thermally conductive components may still provide a certain level of heat dissipation effect to the heat source.

In addition, the thermally conductive components are thermally coupled to the cold plate, and the thermally conductive components extend from one side of the cold plate located closer to the thermally coupling surface to another side of the cold plate located closer to the heat dissipation surface, which can rapidly conduct heat to the fin assembly thermally coupled to the cold plate when the valve connected to the cold plate is closed due to a leakage. As a result, the large heat dissipation surface of the fin assembly can be effectively used for helping to dissipate heat generated by the heat source.

Furthermore, when the module controller receives the leakage signal transmitted from the leakage detector, the module controller closes the valve connected to the cold plate and activates the air cooling assembly for generating airflow towards the fin assembly thermally coupled to the cold plate, which can carry away heat conducted to the cold plate and the fin assembly in a forced convection manner for further facilitating heat dissipation for the heat source.

On the other hand, since the valve and the air cooling assembly both are controlled by the module controller, the closing of the valve and the activation of the air cooling assembly can be performed by the module controller simultaneously. Therefore, in a condition that the heat source is unable to be cooled by the liquid cooling manner due to a leakage, the air cooling manner can be immediately adopted to dissipate heat generated by the heat source, thereby provide a certain level of heat dissipation effect to the heat source. As a result, even though the operation of the heat source is required to wait for a period of time to be adjusted (e.g., reduced power or shut down) by the baseboard management controller which controls various electronic components at the same time, the air cooling manner is adopted during this period of time to dissipate heat generated by the heat source, which prevents the heat source from being damaged due to overly high temperature.

Moreover, since the thermally conductive components can conduct heat generated by the heat source to one side of the cold plate located farther away from the heat source for uniformly distributing heat all over the entire cold plate. As a result, in the liquid cooling mode, the heat exchange efficiency between the cold plate and the coolant flowing through the cold plate can be improved, such that the coolant can carry away a larger amount of heat.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. An electronic system, comprising:
a heat source; and
a cooling module, comprising:
a liquid cooling assembly, comprising:
a cold plate, having a fluid chamber, a thermally coupling surface and a heat dissipation surface, wherein the fluid chamber is located between the thermally coupling surface and the heat dissipation surface, and the thermally coupling surface is thermally coupled with the heat source; and
a thermally conductive component, thermally coupled with the cold plate, wherein the thermally conductive component extends from one side of the cold plate located closer to the thermally coupling surface to another side of the cold plate located closer to the heat dissipation surface.

2. The electronic system according to claim 1, wherein the thermally conductive component is embedded into the cold plate.

3. The electronic system according to claim 1, wherein the cold plate comprises a bottom seat and a cover connected to each other, the bottom seat and the cover together form the fluid chamber, the thermally coupling surface is located at the bottom seat, the heat dissipation surface is located at the cover, the thermally conductive component comprises a heat absorbing portion, a transmission portion and a condensation portion, the heat absorbing portion is connected to the condensation portion via the transmission portion, the heat absorbing portion is disposed at the bottom seat, the condensation portion is disposed at the cover, and the transmission portion extends from the bottom seat to the cover.

4. The electronic system according to claim 3, wherein the heat absorbing portion and the condensation portion is non-parallel to a direction of gravity, a capillary structure is provided in each of the heat absorbing portion and the condensation portion, and a groove structure is provided in the transmission portion.

5. The electronic system according to claim 3, wherein the heat absorbing portion and the condensation portion are non-perpendicular to a direction of gravity, a capillary force of a capillary structure in the heat absorbing portion is greater than a capillary force of a capillary structure in the transmission portion, and a groove structure is provided in the condensation portion.

6. The electronic system according to claim 1, wherein the liquid cooling assembly further comprises a fin assembly thermally coupled with the heat dissipation surface of the cold plate.

7. The electronic system according to claim 6, wherein the cooling module further comprises an air cooling assembly disposed aside the fin assembly and configured to generate an airflow towards the fin assembly.

8. The electronic system according to claim 7, wherein the cooling module further comprises a leakage detector and a module controller, the liquid cooling assembly further comprises an inlet pipe, a valve and an outlet pipe, the inlet pipe and the outlet pipe are respectively connected to different positions of the cold plate, the valve is disposed on the inlet pipe, the leakage detector is disposed around the cold plate, the module controller is electrically connected to the valve, the leakage detector and the air cooling assembly, and the module controller is configured to close the valve and activate the air cooling assembly when receiving a leakage signal transmitted from the leakage detector.

9. The electronic system according to claim 8, further comprising a motherboard, a baseboard management controller and a rotational speed sensor, wherein the heat source and the baseboard management controller are disposed on the motherboard, the baseboard management controller is electrically connected to the module controller, the rotational speed sensor is electrically connected to the baseboard management controller and configured to measure a rotational speed information, the baseboard management controller is configured to decrease a power of the heat source or shut down the heat source according to the rotational speed information after receiving the leakage signal transmitted from the module controller.

10. A cooling module, configured to cool a heat source, comprising:
a liquid cooling assembly, comprising:
a cold plate, having a fluid chamber, a thermally coupling surface and a heat dissipation surface, wherein the fluid chamber is located between the thermally coupling surface and the heat dissipation surface, and the thermally coupling surface is configured to be thermally coupled with the heat source; and
a thermally conductive component, thermally coupled with the cold plate, wherein the thermally conductive component extends from one side of the cold plate located closer to the thermally coupling surface to another side of the cold plate located closer to the heat dissipation surface.

11. The cooling module according to claim 10, wherein the thermally conductive component is embedded into the cold plate.

12. The cooling module according to claim 10, wherein the cold plate comprises a bottom seat and a cover connected to each other, the bottom seat and the cover together form the fluid chamber, the thermally coupling surface is located at the bottom seat, the heat dissipation surface is located at the cover, the thermally conductive component comprises a heat absorbing portion, a transmission portion and a condensation portion, the heat absorbing portion is connected to the condensation portion via the transmission portion, the heat absorbing portion is disposed at the bottom seat, the condensation portion is disposed at the cover, and the transmission portion extends from the bottom seat to the cover.

13. The cooling module according to claim 12, wherein the heat absorbing portion and the condensation portion is non-parallel to a direction of gravity, a capillary structure is provided in each of the heat absorbing portion and the condensation portion, and a groove structure is provided in the transmission portion.

14. The cooling module according to claim 12, wherein the heat absorbing portion and the condensation portion are non-perpendicular to a direction of gravity, a capillary force of a capillary structure in the heat absorbing portion is greater than a capillary force of a capillary structure in the transmission portion, and a groove structure is provided in the condensation portion.

15. The cooling module according to claim 10, wherein the liquid cooling assembly further comprises a fin assembly thermally coupled with the heat dissipation surface of the cold plate.

16. The cooling module according to claim 15, further comprising an air cooling assembly disposed aside the fin assembly and configured to generate an airflow towards the fin assembly.

17. The cooling module according to claim 16, further comprising a leakage detector and a module controller, wherein the liquid cooling assembly further comprises an inlet pipe, a valve and an outlet pipe, the inlet pipe and the outlet pipe are respectively connected to different positions of the cold plate, the valve is disposed on the inlet pipe, the leakage detector is disposed around the cold plate, the module controller is electrically connected to the valve, the leakage detector and the air cooling assembly, and the module controller is configured to close the valve and activate the air cooling assembly when receiving a leakage signal transmitted from the leakage detector.

18. The cooling module according to claim 10, wherein a thermal conductivity of the thermally conductive component is greater than a thermal conductivity of the cold plate.

19. A control method of electronic system, comprising:
monitoring a leakage detector via a module controller; and
when the module controller receives a leakage signal transmitted from the leakage detector, the module controller closes a valve connected to a cold plate and activates an air cooling assembly for generating an airflow towards a fin assembly thermally coupled with the cold plate.

20. The control method according to claim 19, wherein after the module controller closes the valve connected to the cold plate and activates the air cooling assembly, the control method further comprises:
measuring a rotational speed of the air cooling assembly via a rotational speed sensor so as to obtain a rotational speed information; and
decreasing a power of a heat source thermally coupled with the cold plate or shutting down the heat source according to the rotational speed information via a baseboard management controller.
